(19) United States
(12) Patent Application Publication
(10) Pub. No.: US 2025/0054792 A1
(43) Pub. Date: Feb. 13, 2025

(54) SUBSTRATE TRANSFER APPARATUS INCLUDING MULTILAYER EFEM

(71) Applicant: VM Inc., Icheonsi (KR)

(72) Inventors: Sang Woo Lee, Suwon-si (KR); Woo Hyung Choi, Seongnam-si (KR)

(73) Assignee: VM Inc., Icheonsi (KR)

(21) Appl. No.: 18/533,010

(22) Filed: Dec. 7, 2023

(30) Foreign Application Priority Data
Aug. 7, 2023 (KR) 10-2023-0102979

(51) Int. Cl. H01L 21/677; B25J 11/00; H01L 21/687

(52) U.S. Cl. CPC H01L 21/67742; B25J 11/0095; H01L 21/67745; H01L 21/68707

(57) ABSTRACT

Disclosed is a substrate transfer apparatus including a first moving plate, a second moving plate located at a lower portion of the first moving plate, and an EFEM including a first rail, a first moving body that is moved on the first rail, and a first robot connected to the moving body and that transports a substrate, and connected to the first moving plate and the second moving plate and that provides the substrate to the first moving plate or the second moving plate.

### CROSS-REFERENCE TO RELATED APPLICATIONS

This application claims priority under 35 U.S.C. § 119 to Korean Patent Application No. 10-2023-0102979 filed on Aug. 7, 2023, in the Korean Intellectual Property Office, the disclosures of which are incorporated by reference herein in their entireties.

### BACKGROUND

Embodiments of the present disclosure described herein relate to a substrate transfer apparatus, and more particularly, relate to a substrate transfer apparatus including a multi-layer EFEM.

It is very important to decrease an area in an equipment used for a semiconductor or display process. For example, a larger number of equipment may be disposed in a factory by decreasing an area occupied by the substrate transfer apparatus whereby productivity and production capacity are enhanced. Furthermore, spaces in the factory may be optimally used due to the decrease in the area whereby an efficiency of use of the spaces may be enhanced and costs may be advantageously reduced, and a movement route may be shortened whereby a movement time may be reduced in a production process, and thus a production line may be optimized. Accordingly, a technology for increasing an amount of processing per unit area of the equipment used for the semiconductor process is necessary.

### SUMMARY

Embodiments of the present disclosure provide a substrate transfer apparatus including an EFEM capable of being moved between multi-layers.

According to an embodiment, a substrate transfer apparatus includes a first moving plate, a second moving plate located at a lower portion of the first moving plate, and an EFEM including a first rail, a first moving body that is moved on the first rail, and a first robot connected to the moving body and that transports a substrate, and connected to the first moving plate and the second moving plate and that provides the substrate to the first moving plate or the second moving plate.

Here, the EFEM may include a second rail disposed on one surface of the first moving body, and the first robot may be configured to be moved on the second rail.

Here, the first rail and the second rail may be disposed to be perpendicular to each other, and the first moving body may be moved on the first rail leftwards and rightwards, and the first robot may be moved on the second rail upwards and downwards.

Here, the EFEM may include a third rail, a second moving body that is moved on the third rail, a fourth rail disposed on one surface of the second moving body, and a second robot that transports the substrate while being moved on the fourth rail, the third rail and the fourth rail may be disposed to be perpendicular to each other, and the second moving body may be moved on the third rail leftwards and rightwards, and the second robot may be moved on the fourth rail upwards and downwards.

Here, the first rail and the third rail may not overlap each other when viewed from a top.

Here, the first robot may be moved on the first rail along a first route, the second robot may be moved on the third rail along a second route, and the first route and the second route may not overlap each other when viewed from a top.

Here, the first robot may deliver the substrate to the second robot by using a first robot arm that is rotatable.

Here, the substrate transfer apparatus may further include a shuttle that is moved on the first moving plate or the second moving plate and that accommodates the substrate, and the first robot may transport the substrate to the shuttle.

Here, a height of the first rail from a ground surface may be larger than a height of the third rail from the ground surface.

Here, the EFEM may include a first auxiliary rail disposed in parallels to the first rail to enhance a stability thereof, and that moves the first moving body.

Here, the EFEM may include a fifth rail disposed on an opposite surface of the first moving body, which faces the one surface of the first moving body such that the first robot is moved on the one surface of the first moving body and the second robot is moved on the opposite surface of the first moving body.

Here, the first rail and the second rail may be connected to each other such that the first robot is moved on the first rail.

Here, the first moving body may include a first sub body and a second sub body, and the second sub body may be connected to the first robot, and may be configured to be inserted into the first sub body to adjust a location of the first robot.

Here, the EFEM may include a third rail, a second moving body that is moved on the third rail, and a second robot connected to the second moving body and that transports the substrate, and the first rail and the third rail may be at least partially overlap each other when viewed from a top.

### BRIEF DESCRIPTION OF THE FIGURES

The above and other objects and features of the present disclosure will become apparent by describing in detail embodiments thereof with reference to the accompanying drawings.

FIG. 1 is a view illustrating a substrate transfer apparatus according to an embodiment;

FIG. 2 is a cross-sectional view illustrating an EFEM according to an embodiment;

FIG. 3 is a cross-sectional view illustrating an EFEM according to another embodiment;

FIG. 4 is a view illustrating the EFEM of FIG. 3;

FIG. 5 is a view illustrating an EFEM according to another embodiment;

FIG. 6 is a view illustrating an EFEM according to another embodiment; and

FIG. 7 is a view illustrating the EFEM of FIG. 5 or FIG. 6.

### DETAILED DESCRIPTION

The embodiments disclosed in the specification is for clearly explaining the spirits of the present disclosure to an ordinary person in the art, to which the present disclosure pertains, and thus, the present disclosure is not limited to the embodiments disclosed in the specification, and the scope of the present disclosure should be construed as including corrections or modifications that do not depart from the spirits of the present disclosure.

General terms used as currently widely as possible are selected as the terms used in the specification in consideration of the functions in the present disclosure, but the terms used in the specification may be changed according to an intention of an ordinary person in the art, to which the present disclosure pertains, a precedent, or advent of a new technology. However, unlike this, when a specific term is defined as an arbitrary meaning to be used, the meaning of the term will be described separately. Accordingly, the terms used in the specification should be construed based on not the simple names of the terms but substantial meanings of the terms and the contents over the specification.

The drawings attached to the specification are for easily explaining the present disclosure, and the shapes illustrated in the drawings are exaggerated according to necessities to help understanding of the present disclosure, and thus the present disclosure is not limited by the drawings.

In the specification, when it is determined that a detailed description of known configurations or functions related to the present disclosure may make the essence of the present disclosure unclear, a detailed description thereof will be omitted according to necessities.

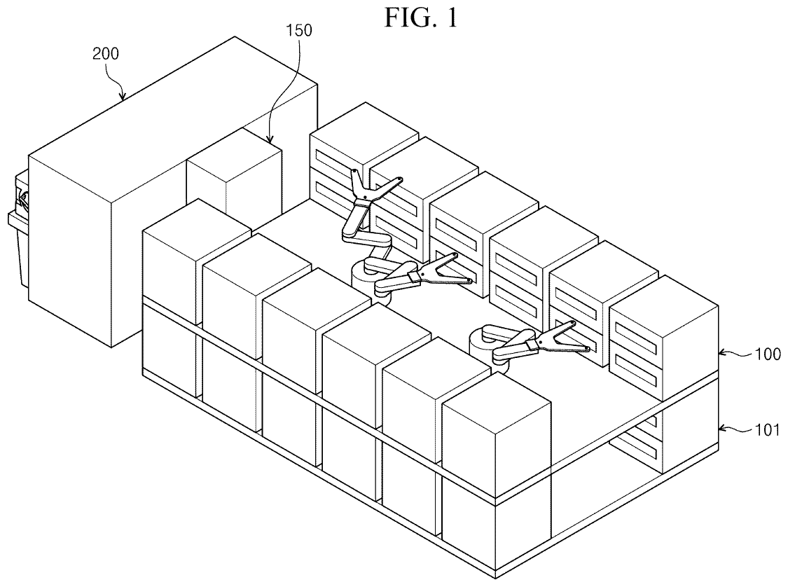

FIG. 1 is a view illustrating a substrate transfer apparatus according to an embodiment.

Referring to FIG. 1, a substrate transfer apparatus according to an embodiment may include a first moving plate 100, a second moving plate 101, a load lock chamber 150, and an equipment front end module (EFEM) 200. Additionally, the substrate transfer apparatus may include a plurality of processing chambers, a plurality of arms, a plurality of shuttles, and rails for the shuttles.

The second moving plate 101 may be disposed at a lower portion of the first moving plate 100. The first moving plate 100 and the second moving plate 101 may be disposed on upper and lower sides whereby the substrate transfer apparatus may have a multi-layer structure.

In the substrate transfer apparatus of the multi-layer structure, the substrate may be transported on the first moving plate 100 or may be transported on the second moving plate 101. The substrate may be moved to an upper layer or a lower layer through the EFEM 200. Accordingly, when a processing chamber that is adjacent to a moving plate breaks down, the substrate transfer apparatus of the multi-layer structure may transport the substrate to a processing chamber that is adjacent to another moving plate.

The load lock chamber 150 may be connected to the first moving plate 100 and the second moving plate 101. The load lock chamber 150 is a module that moves the substrate while being moved between the moving plate and the EFEM while a pressure thereof being converted between the atmospheric pressure and a vacuum pressure. The load lock chamber 150 may be a chamber for maintaining the vacuum or atmospheric state of a substrate that is transported from the first moving plate 100 or the second moving plate 101 to the EFEM 200 or a substrate that is transported inversely.

For example, when the substrate is moved from the EFEM to the moving plate, the load lock chamber 150 may receive a substrate in the atmospheric state from the EFEM, may adjust the pressure to an atmospheric pressure to make the substrate into a plate, in turn may adjust the pressure to a vacuum state, then may open a gate that is close to the moving plate, and may deliver the substrate to the moving plate. Also in an inverse case, when a substrate is moved from the moving plate to the EFEM, the load lock chamber 150 may receive the substrate in the vacuum state from the moving plate, may adjust pressure for the atmospheric state, then may open the gate that is close to the EFEM, and may deliver the substrate to the EFEM.

The EFEM may be an equipment that performs a pre-processing operation, for example, an operation of feeding a substrate. The EFEM 200 may include components, such as a robot arm, an aligner for setting a direction of a substrate, a side storage for removing fumes, a load port, in which a front open unified pod (FOUP) is seated, a sensor that detects a location of the substrate, a vacuum pump, and modules for additional functions.

The present disclosure relates to a substrate transfer apparatus that may move the substrate from any one of the first moving plate 100 and the second moving plate 101 to the other one by using the robot included in the EFEM. Conventionally, an EFEM requires an additional hardware device, such as an escalator or an elevator, to move a substrate between layers. However, the EFEMs are vulnerable to vibrations, for example, the elevators themselves may be moved, and problems related to a possibility of generating particles due to changes in pressures due to the vibrations and movements occur. Furthermore, many efforts and costs are necessary for their designs.

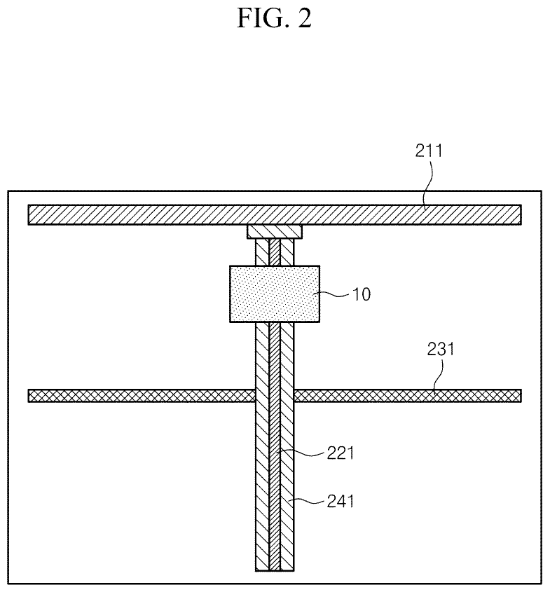

The present disclosure relates to an EFEM that includes a robot that conveniently transports a substrate on a fixed rail to cope with an aspect that it is vulnerable to vibration and a possibility of generating particles. Hereinafter, a substrate transfer apparatus including an EFEM that may be moved between layers will be described in detail with reference to FIGS. 2 to 6.

FIG. 2 is a cross-sectional view illustrating an EFEM according to an embodiment.

Referring to FIG. 2, the EFEM according to an embodiment may include a first rail 211, a first moving body 241, a second rail 221 that is disposed on the first moving body, a first auxiliary rail 231, and a first robot 10. FIG. 2 illustrates a structure that is similar to an “I” shape, in which the first rail 211 and the first auxiliary rail 231 are disposed to be parallel to a ground surface and the second rail 221 is disposed to be perpendicular to the ground surface, but the present disclosure is not limited thereto and an “H”-shaped structure also is possible. For example, the first rail 211 and the first auxiliary rail 231 may be disposed to be perpendicular to the ground surface, and the second rail 221 may be disposed to be parallel to the ground surface.

The first rail 211 and the first auxiliary rail 231 may be rails, locations of which are fixed in an interior of the EFEM. Furthermore, the second rail 221 may be a rail, a location of which is fixed onto the first moving body 241. However, the location of the second rail 221 may be changed in the interior of the EFEM as the first moving body 241 is moved.

The first rail 211 may be configured such that the first moving body 241 may be moved thereon. A leftward/rightward location of the first robot 10 may be changed as the first moving body 241 is moved on the first rail 211. Although not illustrated in FIG. 2, the first robot 10 may be moved not only in the second rail 221 on the first moving body 241 but also on the first rail 211. Then, the first rail 211 and the second rail 221 may be connected to each other such that the first robot 10 may be moved on the first rail 211.

The first moving body 241 may be disposed on and connected to the first rail 211 to be perpendicular thereto. The first moving body 241 may be moved on the first rail 211 to move the first robot 10 leftwards and rightwards. A shape of the first moving body 241 may be various shapes, such as a cylindrical shape and a polygonal column shape. The first moving body 241 may include the second rail 221 that is disposed on one surface thereof.

Due to an upward/downward length of the first moving body 241, resistances of the air during movement thereof, and the like, a problem of firmness, stability, or the like may occur when the first moving body 241 is moved on the first rail 211. Accordingly, the EFEM may enhance the stability of the movement of the first moving body 241 by using the first auxiliary rail 231.

In detail, the first auxiliary rail 231 may be connected to one area of the first moving body 241. FIG. 2 illustrates that the first auxiliary rail 231 is connected to a central portion of the first moving body 241, but the present disclosure is not limited thereto and a connection point of the first auxiliary rail 231 may be determined variously. The first moving body 241 may be moved leftwards and rightwards along the rail by using the first auxiliary rail 231 as well as the first rail 211. Accordingly, even when the first moving body 241 is long or is moved fast, the stability and the firmness of the movement of the first moving body 241 in the interior of the EFEM may be enhanced by using two rails. FIG. 2 illustrates an example of using one auxiliary rail, but the present disclosure is not limited thereto and the number of auxiliary rails may be plural according to necessities.

The second rail 221 may be disposed on one surface of the first moving body 241. The second rail 221 may be configured such that the first robot 10 may be moved thereon. For example, the first robot 10 may be moved on the second rail 221 by using a wheel. However, the present disclosure is not limited thereto, and the second rail 221 may be implemented in various forms, such as a sliding or a fixed rail.

The first moving body 241 may include another rail as well as the second rail 221. In detail, the second rail 221 may be disposed on one surface of the first moving body 241, and another rail (not illustrated) may be disposed on an opposite surface that faces the one surface. Accordingly, the first robot 10 may be moved on the one surface of the first moving body 241 by using the second rail 221, and another robot may be moved on the opposite surface by using another rail (for example, a fifth rail). That is, the first moving body 241 may include two or more rails to move two or more robots.

The first robot 10 may include a robot arm that may grip a substrate. The first robot 10 may be moved on the second rail 221 to transport the substrate. In addition, according to occasions, the first robot 10 also may be moved on the first rail 211 or the first auxiliary rail 231.

In detail, the first moving body 241 may be moved on the first rail 211 leftwards and rightwards, and the first robot 10 may transport the substrate on the same layer as that of the first moving plate 100 while gripping it. Furthermore, the first robot 10 may be moved on the second rail 221 upwards and downwards to change the layer of the substrate such that the substrate may be moved from any one of the first moving plate 100 and the second moving plate 101 to the other one.

FIG. 2 illustrates the second rail 221 that is disposed to be perpendicular to the first rail 211 and the first auxiliary rail 231, but the present disclosure is not limited thereto and an angle defined by the second rail 221 and the first rail 211 or the first auxiliary rail 231 may be changed. For example, one end of the second rail 221 may be connected to a left end of the first rail 211, and an opposite end of the second rail 221 may be connected to a right end of the first auxiliary rail 231. Accordingly, the EFEM may include a rail in a form of a “Z”-shaped structure or an inverse “Z”-shaped structure.

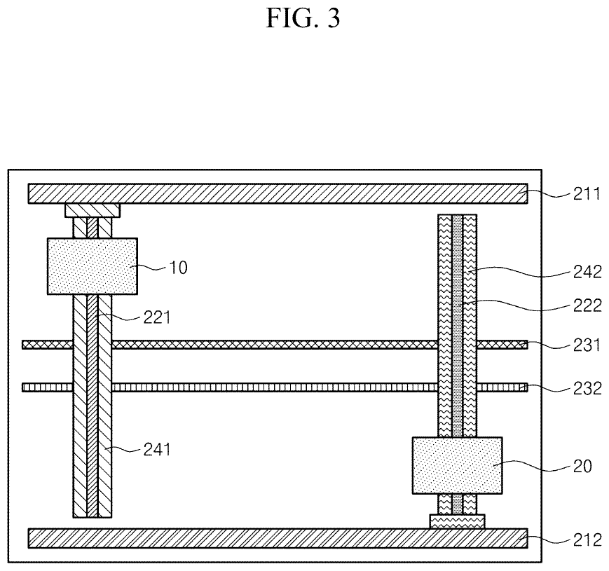

FIG. 3 is a cross-sectional view illustrating an EFEM according to another embodiment.

Referring to FIG. 3, the EFEM according to another embodiment may include the first rail 211, the first moving body 241, the second rail 221 that is disposed on the first moving body 241, the first rail 211, the first robot 10, a third rail 212, the second moving body 242, a fourth rail 222 that is disposed on a second moving body 242, a second auxiliary rail 232, and a second robot 20. The EFEM of FIG. 3 is an example of using two moving bodies and two robots.

The EFEM may include a plurality of robots to move and transport a substrate between layers. The plurality of robots may transport substrates independently, and may transport a substrate while delivering the substrate of one robot to another robot. The plurality of robots may be moved independently. In detail, the first robot 10 may be moved leftwards and rightwards through the first rail 211 and the first moving body 241, and may be moved upwards and downwards through the second rail 221. Furthermore, the second robot 20 may be moved leftwards and rightwards through the third rail 212 and the second moving body 242, and may be moved upwards and downwards through the fourth rail 222. In addition, the first robot 10 and the second robot 20 may be moved to various locations not only leftwards and rightwards and upwards and downward by using the plurality of rails, the moving bodies, rotations, and the robot arms, but also through changes of their locations and rotations thereof.

The third rail 212 and the second auxiliary rail 232 may be rails, locations of which are fixed in the interior of the EFEM. Furthermore, the fourth rail 222 may be a rail, a location of which is fixed onto the second moving body 242. However, the location of the fourth rail 222 may be changed in the interior of the EFEM as the second moving body 242 is moved.

The third rail 212 may be configured such that the second moving body 242 may be moved thereon. The second moving body 242 may be moved on the third rail 212 to change a leftward/rightward location of the second robot 20. Although not illustrated in FIG. 3, the second robot 20 may be moved not only on the fourth rail 222 on the second moving body 242 but also on the third rail 212. Then, the third rail 212 and the fourth rail 222 may be connected to each other such that the second robot 20 may be moved on the third rail 212.

The second moving body 242 may be disposed in and connected to the third rail 212 to be perpendicular thereto. The second moving body 242 may be moved on the third rail 212 to move the second robot 20 leftwards and rightwards. A shape of the second moving body 242 may various shapes, such as a cylindrical shape and a polygonal column shape. The second moving body 242 may include the fourth rail 222 that is disposed on one surface thereof.

Due to an upward/downward length of the second moving body 242, resistances of the air during movement thereof, and the like, a problem of firmness, stability, or the like may occur when the second moving body 242 is moved on the third rail 212. Accordingly, the EFEM may enhance a stability of the movement of the second moving body 242 by using the second auxiliary rail 232.

In detail, the second auxiliary rail 232 may be connected to one area of the second moving body 242. FIG. 3 illustrates that the second auxiliary rail 232 is connected to a central portion of the second moving body 242, but the present disclosure is not limited thereto and a connection point of the second auxiliary rail 232 may be determined variously. The second moving body 242 may be moved leftwards and rightwards along the rail by using the second auxiliary rail 232 as well as the third rail 212. Accordingly, even when the second moving body 242 is long or is moved fast, the stability and the firmness of the movement of the second moving body 242 in the interior of the EFEM may be enhanced by using two rails. FIG. 3 illustrates an example of using one auxiliary rail, but the present disclosure is not limited thereto and the number of auxiliary rails may be plural according to necessities. Furthermore, the first auxiliary rail 231 and the second auxiliary rail 232 may be integrated according to occasions to be expressed as one auxiliary rail.

The first auxiliary rail 231 and the second auxiliary rail 232 may be disposed at locations, at which the first robot 10 and the second robot 20 are not obstructed when they transport a substrate to the load lock chamber. For example, the first auxiliary rail 231 and the second auxiliary rail 232 may be disposed to be connected to one of the surfaces of the first moving body 241 and the second moving body 242, which is not close to the load lock chamber.

The fourth rail 222 may be disposed on one surface of the second moving body 242. The fourth rail 222 may be configured such that the second robot 20 may be moved thereon. For example, the second robot 20 may be moved on the fourth rail 222 by using a wheel. However, the present disclosure is not limited thereto, and the fourth rail 222 may be implemented in various forms, such as a sliding rail or a fixed rail.

The second moving body 242 may include another rail, as well as the fourth rail 222. In detail, the fourth rail 222 may be disposed on one surface of the second moving body 242, and another rail (not illustrated) may be disposed on an opposite surface that faces the one surface. Accordingly, the second robot 20 may be moved on the one surface of the second moving body 242 by using the fourth rail 222, and another robot may be moved on the opposite surface by using another rail. That is, the second moving body 242 may include two or more rails to move two or more robots.

The first moving body 241 and the second moving body 242 may be disposed to be spaced apart from each other to prevent a collision when the first robot 10 and the second robot 20 are moved leftwards and rightwards. Accordingly, the first rail 211 and the third rail 212 may be disposed to be spaced apart from each other to space the first moving body 241 and the second moving body 242 apart from each other. For example, when viewed from a top, the first rail 211 and the third rail 212 may be disposed to be spaced apart from each other by a specific distance.

Alternatively, to prevent collision of the first robot 10 and the second robot 20, a structure of the first moving body 241 and the second moving body 242, instead of the first rail 211 and the third rail 212, may be set. For example, when viewed from a top, the first rail 211 and the third rail 212 may be disposed to overlap each other, the first moving body 241 may be disposed on a left side of the first rail 211 and the third rail 212, and the second moving body 242 may be disposed on a right side of the first rail 211 and the third rail 212. However, the present disclosure is not limited thereto, and various disposition structures of rails and moving bodies for collision of the first robot 10 and the second robot 20 may be applied.

Through the movement of the first moving body 241 on the first rail 211 and/or the first auxiliary rail 231 and the movement of the first robot 10 on the second rail 221, the first robot 10 may transport a substrate located on an upper layer or may transport a substrate to the upper layer. Furthermore, through the movement of the second moving body 242 on the third rail 212 and/or the second auxiliary rail 232 and the movement of the second robot 20 on the fourth rail 222, the second robot 20 may transport a substrate located on an upper layer or may transport a substrate to the upper layer.

The first robot 10 may deliver or receive the substrate to or from the second robot 20. Then, the first robot 10 may deliver or receive the substrate to or from the second robot 20 on the second rail 221 by using the first robot arm, but the present disclosure is not limited thereto, and it may deliver or receive the substrate on the first rail 211.

The second robot 20 may deliver or receive the substrate to or from the first robot 10. Then, the second robot 20 may deliver or receive the substrate to or from the first robot 10 on the fourth rail 222 by using the second robot arm, but the present disclosure is not limited thereto, and it may deliver or receive the substrate on the third rail 212.

The first robot 10 or the second robot 20 may transport the substrate to the shuttle. The shuttle is a device that is configured to accommodate the substrate, and may include a space that may accommodate the substrate in an interior thereof. In detail, the shuttle may be moved to the load lock chamber 150 that is connected to the EFEM 200, to deliver or receive the substrate. The first robot 10 or the second robot 20 may transport a substrate to the shuttle in the load lock chamber 150 or extract a substrate in the shuttle. Accordingly, the shuttle may be moved to the first moving plate 100 or the second moving plate 101.

The first rail 211 may be located on an upper side of the third rail 212. In detail, a height of the first rail 211 from the ground surface is larger than a height of the third rail 212 from the ground surface. For example, the first rail 211 may be disposed on a ceiling of the EFEM and the third rail 212 may be disposed on a bottom of the EFEM, but the present disclosure is not limited thereto. The heights of the first rail 211 and the third rail 212 may be set differently whereby an efficiency of the movement between the moving bodies may be enhanced and sizes of the rails and the moving bodies in the interior of the EFEM may be reduced.

FIG. 3 illustrates that the first rail 211, to which the first moving body 241 is connected, and the third rail 212, to which the second moving body 242 is connected, are disposed on upper and lower sides in the interior of the EFEM. However, the disposition of the first rail 211 and the third rail 212 are not limited thereto, and may have various disposition forms.

For example, the first rail 211 may be disposed at an upper portion of the EFEM, and the third rail 212 may be disposed on a left side or a right side of the EFEM. Accordingly, the second moving body 242 may be moved on the third rail 212 upwards and downwards, and the second robot 20 may be moved on the second moving body 242 leftwards and rightwards. In this case, when viewed from a top, at least areas of the first rail 211 and the third rail 212 may overlap each other.

Furthermore, for example, the first rail 211 may be disposed on the left or right side of the EFEM, and the third rail 212 may be disposed on a lower side of the EFEM. Accordingly, the first moving body 241 may be moved on the first rail 211 upwards and downwards, and the first robot 10 may be moved on the first moving body 241 leftwards and rightwards. In this case, when viewed from a top, at least areas of the first rail 211 and the third rail 212 may overlap each other.

Furthermore, for example, the first rail 211 may be disposed on a left side of the EFEM, and the third rail 212 may be disposed on a right side of the EFEM. Accordingly, the first moving body 241 may be moved on the first rail 211 upwards and downwards, and the first robot 10 may be moved on the first moving body 241 leftwards and rightwards. Furthermore, the second moving body 242 may be moved on the third rail 212 upwards and downwards, and the second robot 20 may be moved on the second moving body 242 leftwards and rightwards. In this case, when viewed from a top, at least areas of the first rail 211 and the third rail 212 may not overlap each other.

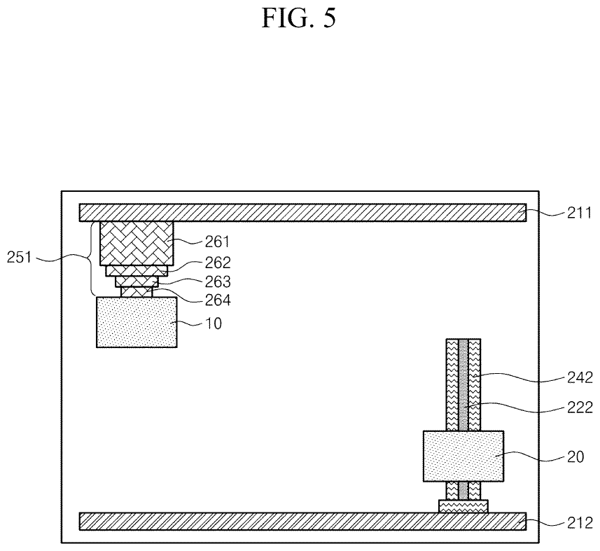

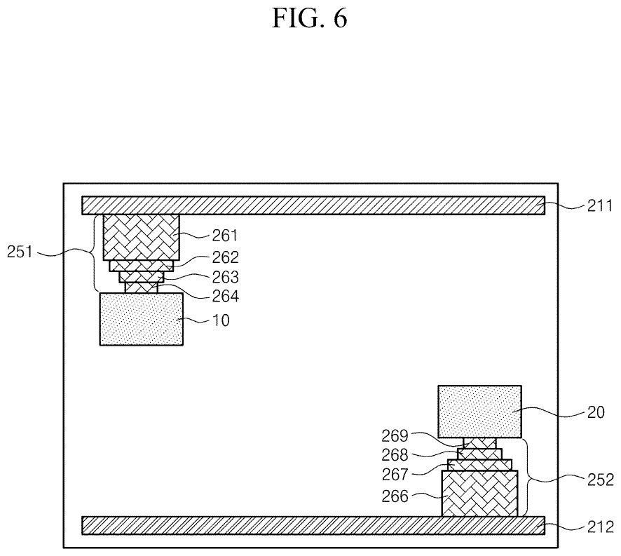

The above-described various disposition forms of the first rail 211 and the third rail 212 may be applied to the embodiments of FIG. 5 and FIG. 6 as well as the embodiment of FIG. 3.

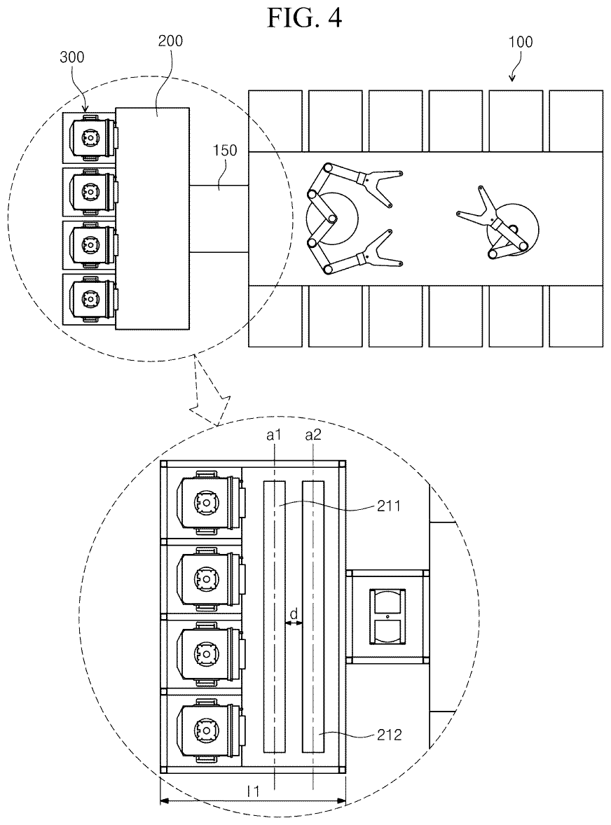

FIG. 4 is a view illustrating the EFEM of FIG. 3. In detail, FIG. 4 is a view illustrating a state, in which the substrate transfer apparatus or the EFEM of FIG. 3 is projected from the top.

Referring to FIG. 4, the EFEM may include rails that are configured such that only the robots may be moved thereon, to independently move the first robot 10 and the second robot 20 while they are prevented from interfering with each other. For example, the EFEM may include the first rail 211 that is configured such that only the first robot 10 may be moved thereon, and the third rail 212 that is configured such that only the second robot 20 may be moved thereon.

Then, when viewed from a top, the first rail 211 and the third rail 212 may be disposed to be spaced apart from each other at a specific distance “d”. In detail, the first rail 211 and the third rail 212 may be parallel rails, and may be spaced apart from each other at the specific distance “d” in a direction that is perpendicular to the axes of the rails. Because the rails are spaced apart from each other, the first robot 10 or the second robot 20 may be moved freely while not colliding with each other.

Furthermore, the first rail 211 and the third rail 212 are not limited to the disposition of FIG. 4, and another disposition, in which routes of the first robot 10 and the second robot 20 are prevented from overlapping each other, may be applied. In detail, when viewed from a top, the first robot 10 may be moved in a first route along a first axis a1, and the second robot 20 may be moved in a second route along a second axis a2. Accordingly, the first rail 211 and the third rail 212 may be disposed such that the first route and the second route may not overlap each other.

For example, the first rail 211 and the third rail 212 may be disposed to overlap each other when viewed from a top, the first moving body 241 connected to the first rail 211 may protrude leftwards in a stapler form to be moved, and the second moving body 242 connected to the third rail 212 protrudes rightwards in a stapler form whereby the first route and the second route may be prevented from overlapping each other. Accordingly, when viewed form a top, the first rail 211 and the third rail 212 may be disposed to be spaced apart from each other, but the present disclosure is not limited thereto, and the movement routes of the first robot 10 and the second robot 20 may be disposed not to overlap each other (such that there is no contact point) even through the first rail 211 and the third rail 212 overlap each other.

FIG. 5 is a view illustrating an EFEM according to another embodiment.

Referring to FIG. 5, the EFEM according to another embodiment may include the first rail 211, a first moving body 251, the first robot 10, the third rail 212, the second moving body 242, the fourth rail 222 that is disposed on the second moving body 242, and the second robot 20. The EFEM of FIG. 5 is different from the EFEM of FIG. 3 in the form of the first moving body 251.

In detail, the first moving body 251 of FIG. 5 does not include any rail unlike the second moving body 242. The first moving body 251 may be moved on the first rail 211 to change a leftward/rightward location of the first robot 10. However, unlike the embodiment of FIG. 3, the first moving body 251 may have a form that may extend upwards and downwards to change the upward/downward location of the first robot 10.

The first moving body 251 may include a plurality of sub bodies. In detail, the first moving body 251 may include a first sub body 261, a second sub body 262, a third sub body 263, and a fourth sub body 264. FIG. 5 illustrates that the first moving body 251 includes the four sub bodies, but the number of sub bodies is not limited thereto and may be different according to a size of the EFEM.

The first sub body 261 may be located on an upper side of the first moving body 251 to be moved on the first rail 211 along the first rail 211. The first sub body 261 may be connected to the second to fourth sub bodies 262 to 264, and may accommodate them. In detail, the second to fourth sub bodies 262 to 264 may be inserted into an interior of the first sub body 261. Furthermore, the second to fourth sub bodies 262 to 264 may be extracted to an outside of the first sub body 261 through a control thereof.

The first to fourth sub bodies 261 to 264 all may have different sizes. In detail, the fourth sub body 264 may have a size that is smaller than that of the third sub body 263 to be inserted into an interior of the third sub body 263. Furthermore, the third sub body 263 may have a size that is smaller than that of the second sub body 262 to be inserted into an interior of the second sub body 262. Furthermore, the second sub body 262 may have a size that is smaller than that of the first sub body 261 to be inserted into an interior of the first sub body 261.

The fourth sub body 264 is a distal sub body of the first moving body 251 and may be connected to the first robot 10. A height of the first robot 10 may be adjusted by inserting and extracting the second to fourth sub bodies 262 to 264.

The first to fourth sub bodies 261 to 264 may be connected to each other, and an entire length thereof may be extended. For example, to lower the height of the first robot 10 by a first length in a basic state (a state, in which all of the second to fourth sub bodies 262 to 264 are inserted into the interior of the first sub body 261), the fourth sub body 264 may be extracted from the third sub body 263.

Furthermore, for example, to lower the height of the first robot 10 by a second length that is larger than the first length in the basic state, the fourth sub body 264 may be extracted from the third sub body 263 and the third sub body 263 may be extracted from the second sub body 262. In this way, to adjust the height of the first robot 10, the second to fourth sub bodies 262 to 264 may be sequentially inserted or extracted.

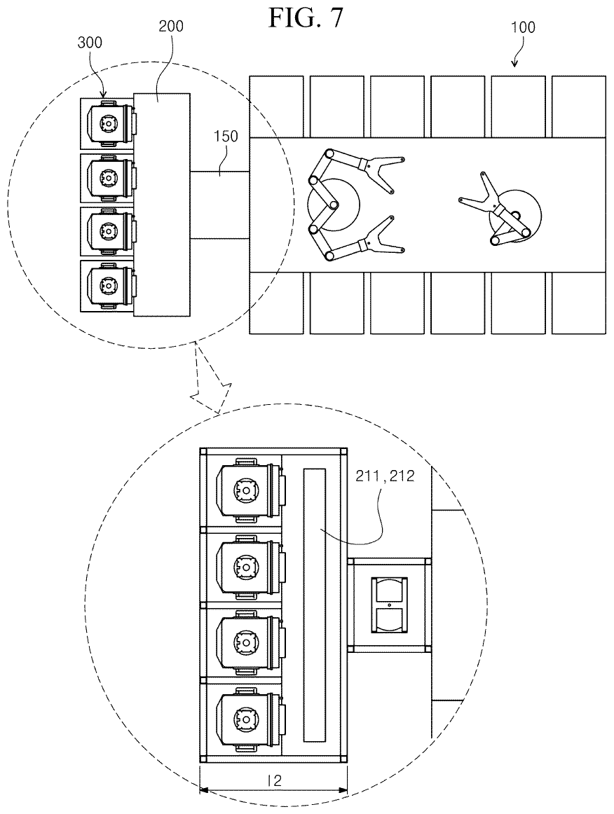

Unlike the first moving body 251, the second moving body 242 may be configured in the same form as in the EFEM of FIG. 3. In the EFEM of FIG. 5, an upward/downward length of the first moving body 251 or the height of the first robot 10 from the ground surface may be adjusted, and thus, the first rail 211 and third rail 212 may overlap each other when viewed from a top. That is, like FIG. 3, the EFEM of FIG. 2 includes the first rail 211 and the third rail 212 that are disposed to be spaced apart from each other when viewed from a top, but the EFEM of FIG. 5 may include the first rail 211 and the third rail 212, at least portions of which overlap each other when viewed from a top. The contents will be described below with reference to FIG. 7.

FIG. 6 is a view illustrating an EFEM according to another embodiment.

Referring to FIG. 6, the EFEM according to another embodiment may include the first rail 211, the first moving body 251, the first robot 10, the third rail 212, a second moving body 252, and the second robot 20. In the EFEM of FIG. 6, the form of the second moving body 252 may be the same as that of the first moving body 251 of FIG. 5.

In detail, the first moving body 251 and the second moving body 252 of FIG. 6 may include a plurality of sub bodies. The first moving body 251 and the second moving body 252 may include a plurality of sub bodies that may extend upwards and downwards to adjust heights of the first robot 10 and the second robot 20. A detailed description of the first moving body 251 is the same as that of FIG. 5, and will be omitted.

The second moving body 252 may include a plurality of sub bodies. In detail, the second moving body 252 may include a fifth sub body 266, a sixth sub body 267, a seventh sub body 268, and an eighth sub body 269. FIG. 6 illustrates that the second moving body 252 includes four sub bodies, but the number of sub bodies is not limited thereto and may be different according to a size of the EFEM.

The fifth sub body 266 may be located on a lower side of the second moving body 252 to be moved on the third rail 212 leftwards and rightwards along the third rail 212. The fifth sub body 266 may be connected to the sixth to eighth sub bodies 267 to 269 and may accommodate them. In detail, the sixth to eighth sub bodies 267 to 269 may be inserted into an interior of the fifth sub body 266. Furthermore, the sixth to eighth sub bodies 267 to 269 may be extracted to an outside of the fifth sub body 266 through a control. An insertion or extraction direction of the sub bodies of the second moving body 252 may be opposite to that of the sub bodies of the first moving body 251.

The fifth to eighth sub bodies 266 to 269 all may have different sizes. In detail, the eighth sub body 269 may have a size that is smaller than that of the seventh sub body 268 to be inserted into an interior of the seventh sub body 268. Furthermore, the seventh sub body 268 may have a size that is smaller than that of the sixth sub body 267 to be inserted into an interior of the sixth sub body 267. Furthermore, the sixth sub body 267 may have a size that is smaller than that of the fifth sub body 266 to be inserted into the fifth sub body 266.

The eighth sub body 269 is a distal sub body of the first moving body 251, and may be connected to the second robot 20. A height of the second robot 20 may be adjusted by inserting or extracting the sixth to eighth sub bodies 267 to 269.

The fifth to eighth sub bodies 266 to 269 may be connected to each other, and an entire length thereof may be extended. For example, to increase the height of the second robot 20 by a third length in a basic state (a state, in which all of the sixth to eighth sub bodies 267 to 269 are inserted into the interior of the fifth sub body 266), the eighth sub body 269 may be extracted from the seventh sub body 268.

Furthermore, for example, to increase the height of the second robot 20 by a fourth length that is larger than the third length in the basic state, the eighth sub body 269 may be extracted from the seventh sub body 268 and the seventh sub body 268 may be extracted from the sixth sub body 267. In this way, to adjust the height of the second robot 20, the sixth to eighth sub bodies 267 to 269 may be sequentially inserted or extracted.

In the EFEM of FIG. 6, upward/downward lengths of the first moving body 251 and the second moving body 252 or the heights of the first robot 10 and the second robot 20 from the ground surface may be adjusted, and thus, the first rail 211 and third rail 212 may overlap each other when viewed from a top. That is, the EFEM of FIG. 2 includes the first rail 211 and the third rail 212 that are disposed to be spaced apart from each other as in FIG. 3 when viewed from a top, but the EFEM of FIG. 6 may include the first rail 211 and the third rail 212, at least portions of which overlap each other when viewed from a top. The contents will be described in detail with reference to FIG. 7.

FIG. 7 is a view illustrating the EFEM of FIG. 5 or FIG. 6. In detail, FIG. 7 is a view illustrating a state, in which the substrate transfer apparatus or the EFEM of FIG. 5 or FIG. 6 is projected from a top.

Referring to FIG. 7, the EFEM may include rails that are configured such that only the robots may be moved thereon, to independently move the first robot 10 and the second robot 20 while they are prevented from interfering with each other. For example, the EFEM may include the first rail 211 that is configured such that only the first robot 10 may be moved thereon, and the third rail 212 that is configured such that only the second robot 20 may be moved thereon.

Then, at least portions of the first rail 211 and the third rail 212 may overlap each other when viewed from a top. For efficient use of areas, preferably, the first rail 211 and the third rail 212 may fully overlap each other when viewed from a top. Accordingly, because the at least portions of the first rail 211 and the third rail 212 overlap each other, an area occupied by the EFEM may be reduced. To cause the at least portions of the first rail 211 and the third rail 212 to overlap each other, the disposition of the rails and the configuration of the moving bodies in the form illustrated in FIG. 5 or FIG. 6 may be applied.

In detail, referring to the EFEM of FIG. 5, because the height of the first moving body 251 may be adjusted, the first moving body 251 may be prevented from colliding with the second moving body 242 by adjusting the height even though the first moving body 251 and the second moving body 242 are moved leftwards and rightwards. Accordingly, the first robot 10 may be independently moved while neither colliding with the second robot 20 nor interfering with it.

In detail, referring to the EFEM of FIG. 6, because the heights of the first moving body 251 and the second moving body 252 may be adjusted, the first moving body 251 and the second moving body 252 may be prevented from colliding with each other by adjusting the height even though the first moving body 251 and the second moving body 252 are moved leftwards and rightwards. Accordingly, the first robot 120 may be independently while neither colliding with the second robot 20 nor interfering with it.

In the EFEM of FIG. 5 or FIG. 6, because there occurs neither a collision between the first moving body 251 and the second moving body 242 or 252 nor a collision between the first robot 10 and the second robot 20, the first rail 211 and the third rail 212 may be disposed such that at least portions thereof overlap each other, without having to be spaced apart from each other. Accordingly, the at least portions of the first rail 211 and the third rail 212 may overlap each other and thus, the areas occupied by the first rail 211 and the third rail 212 may be reduced whereby a size of the EFEM may be reduced.

In detail, in FIG. 3, the first rail 211 and the third rail 212 are spaced apart from each other by a spacing distance “d” when viewed from a top, a length of one surface of the EFEM becomes a first length 11. However, in FIG. 7, because the at least portions of the first rail 211 and the third rail 212 overlap each other when viewed from a top, a length of one surface of the EFEM may become a second length 12 that is smaller than the first length 11. Accordingly, as the size of the EFEM is reduced, an entire size of the substrate transfer apparatus may be reduced.

According to an embodiment of the present disclosure, a substrate transfer apparatus including an EFEM capable of being moved between multi-layers may be provided.

The methods according to the embodiments may be implemented in a form of program instructions that may be performed through various computer means and may be recorded in a computer readable medium. The computer readable medium may include program instructions, data files, or data structures alone or in combination. The program instructions recorded in the medium may be particularly designed and configured for the embodiments, or may be known to an ordinary person in a computer software field to be used. Examples of computer readable recording mediums include hardware devices, such as magnetic media, such as hard disks, floppy disks, and magnetic tapes, optical media, such as CD-ROMs and DVDs, magneto-optical media, such as floptical disks, ROMs, RAMs, and flash memories, which are particularly configured to store and perform program instructions. Examples of program instructions include high-level language codes that may be executed by computers by using interpreters, as well as machine language codes that are made by compilers. The hardware devices may be configured to be operated as one or more software modules to perform operations of the embodiments, and reverse cases may be possible.

In this way, although the embodiments have been described with reference to the limited embodiments and the drawings, an ordinary person in the art, to which the present disclosure pertains, may make various corrections and modifications from the description. For example, the described technology may achieve suitable results even though they are performed in sequences that are different from those of the described method and/or the components, such as the described systems, structures, devices, or circuits, are coupled or combined in a form that is different from that of the described method or replaced by other components or equivalents.

Therefore, other implementations, other embodiments, and equivalents to the claims pertain to the scope of the claims, which will be described above.

What is claimed is:

1. A substrate transfer apparatus comprising:
a first moving plate;
a second moving plate located at a lower portion of the first moving plate; and
an equipment front end module (EFEM) including a first rail, a first moving body configured to be moved on the first rail, and a first robot connected to the first moving body and configured to transport a substrate, and connecting to the first moving plate and the second moving plate to provide the substrate to the first moving plate or the second moving plate.

2. The substrate transfer apparatus of claim 1, wherein the EFEM includes a second rail disposed on one surface of the first moving body, and
wherein the first robot is configured to be moved on the second rail.

3. The substrate transfer apparatus of claim 2, wherein the first rail and the second rail are disposed to be perpendicular to each other, and
wherein the first moving body is moved on the first rail leftwards and rightwards, and the first robot is moved on the second rail upwards and downwards.

4. The substrate transfer apparatus of claim 2, wherein the EFEM includes a third rail, a second moving body configured to be moved on the third rail, a fourth rail disposed on one surface of the second moving body, and a second robot configured to transport the substrate while being moved on the fourth rail,
wherein the third rail and the fourth rail are disposed to be perpendicular to each other, and
wherein the second moving body is moved on the third rail leftwards and rightwards, and the second robot is moved on the fourth rail upwards and downwards.

5. The substrate transfer apparatus of claim 4, wherein the first rail and the third rail do not overlap each other when viewed from a top.

6. The substrate transfer apparatus of claim 4, wherein the first robot is moved on the first rail along a first route,
wherein the second robot is moved on the third rail along a second route, and
wherein the first route and the second route do not overlap each other when viewed from a top.

7. The substrate transfer apparatus of claim 4, wherein the first robot delivers the substrate to the second robot by using a first robot arm that is rotatable.

8. The substrate transfer apparatus of claim 1, further comprising:
a shuttle configured to be moved on the first moving plate or the second moving plate and configured to accommodate the substrate,
wherein the first robot transports the substrate to the shuttle.

9. The substrate transfer apparatus of claim 4, wherein a height of the first rail from a ground surface is larger than a height of the third rail from the ground surface.

10. The substrate transfer apparatus of claim 1, wherein the EFEM includes a first auxiliary rail disposed in parallels to the first rail to enhance a stability thereof, and configured to move the first moving body.

11. The substrate transfer apparatus of claim 2, wherein the EFEM includes a fifth rail disposed on an opposite surface of the first moving body, which faces the one surface of the first moving body such that the first robot is moved on the one surface of the first moving body and the second robot is moved on the opposite surface of the first moving body.

12. The substrate transfer apparatus of claim 2, wherein the first rail and the second rail are connected to each other such that the first robot is moved on the first rail.

13. The substrate transfer apparatus of claim 1, wherein the first moving body includes a first sub body and a second sub body, and
wherein the second sub body is connected to the first robot, and is configured to be inserted into the first sub body to adjust a location of the first robot.

14. The substrate transfer apparatus of claim 13, wherein the EFEM includes a third rail, a second moving body configured to be moved on the third rail, and a second robot connected to the second moving body and configured to transport the substrate, and
wherein the first rail and the third rail are at least partially overlap each other when viewed from a top.
